(19) United States
(12) Patent Application Publication
(10) Pub. No.: US 2010/0243024 A1
(43) Pub. Date: Sep. 30, 2010

(54) SOLAR CELL, SOLAR CELL MODULE AND SOLAR CELL SYSTEM

(75) Inventors: Haruhisa HASHIMOTO, Minoh City (JP); Tasuku ISHIGURO, Kobe City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD, Moriguchi City (JP)

(21) Appl. No.: 12/727,810

(22) Filed: Mar. 19, 2010

(30) Foreign Application Priority Data
Mar. 31, 2009 (JP) 2009-085599

(51) Int. Cl. H01L 31/042; H01L 31/00

(52) U.S. Cl. 136/244; 136/256

(57) ABSTRACT

A solar cell includes: a front surface electrode having a first current-collecting electrode and non-straight line electrodes connected to the first current-collecting electrode; a semiconductor substrate serving as a photoelectric conversion body; and a rear surface electrode having a second current-collecting electrode and line electrodes connected to the second current-collecting electrode. The front surface electrode, the semiconductor substrate and the rear surface electrode are arranged in that order. The non-straight line electrodes of the front surface electrode and the line electrodes of the rear surface electrodes are opposed to each other with the semiconductor substrate interposed there-between. The non-straight line electrodes of the front surface electrode and the line electrodes of the rear surface electrodes are different in shape while having a portion where the electrodes intersect each other, as seen in a direction perpendicular to the front surface of the semiconductor substrate.

### CROSS REFERENCE TO RELATED APPLICATIONS

This application of the invention titled “Solar Cell, Solar Cell Module and Solar Cell System” is based upon and claims the benefit of priority under 35 USC 119 from prior Japanese Patent Application No. 2009-085599, filed on Mar. 31, 2009; the entire contents of which are incorporated herein by reference.

### BACKGROUND OF THE INVENTION

1. Field of the Invention

The invention relates to a solar cell, a solar cell module and a solar cell system.

2. Description of the Related Art

A solar cell system provided with solar cells is expected to be a new energy conversion system that converts light from the sun into electricity. In recent years, active use of solar cell systems has been increasing as a general household power supply and a large-scale power generation plant.

Currently research and development for cost reduction of solar cell systems is actively in progress in order to further spread the use solar cell systems.

A conventional solar cell system includes one or more solar cell modules, for example. The solar cell module includes a plurality of solar cells electrically connected to each other. Each of the solar cells is provided with: a semiconductor substrate forming a photoelectric conversion body; a front surface electrode on the front surface of the semiconductor substrate; and a rear surface electrode on the rear surface of the semiconductor substrate.

The front surface electrode of one of adjacent solar cells is connected to the rear surface electrode of the other one of the adjacent solar cells with a conductive connection member such as copper foil by soldering or the like.

The front surface electrode includes: a plurality of finger electrodes, each of which is a narrow electrode, formed in the region of substantially the entire surface of the front surface of the solar cell (the front surface of the semiconductor substrate); and wide bus bar electrodes connected to the finger electrodes, for example. Moreover, the rear surface electrode includes: a plurality of finger electrodes, each of which is a narrow electrode, formed in the region of substantially the entire surface of the rear surface of the solar cell (the rear surface of the semiconductor substrate); and wide bus bar electrodes connected to the finger electrodes, for example. Instead, the rear surface electrode may include a metal film formed on substantially the entire rear surface. In particular, the former one including the finger electrodes and bus bar electrodes is employed as the rear surface electrode used for a bifacial solar cell in many cases.

Recently, there is proposed a technique to use a conductive adhesive agent made of resin for connection of the front surface electrode to the rear surface electrode of the solar cell with the conductive connection member such as copper foil (refer to Japanese Patent Application Publication No. 2008-147567, for example).

### SUMMARY OF THE INVENTION

However, the conventional wide bus bar electrodes require the use of a large amount of electrode material, and accordingly often require high cost. To avoid this, it is worthwhile to consider reducing the width of the bus bar electrodes.

Even in a case where narrow bus bar electrodes are used, however, there is a problem that cracks in the substrate occurs easily, thus lowering the production yield of solar cells. The problem occurs due to a configuration in which the bus bar electrodes forming the front surface electrode have the same shape as the bus bar electrodes forming the rear surface electrode, when viewed in a perpendicular direction from the front surface of the solar cell (the semiconductor substrate forming the cell). Here, a large difference in the thermal expansion coefficient between the substrate, the front surface electrode, and the rear surface electrode generates stresses on the front surface side and the rear surface side due to temperature variations during the manufacturing process or the like. In the above configuration, the stresses are added to the substrate in substantially the same direction, and hence cause the substrate to crack easily.

A first aspect of the invention provides a solar cell comprising: a front surface electrode having a first current-collecting electrode and a number N of non-straight line electrodes connected to the first current-collecting electrode; a semiconductor substrate serving as a photoelectric conversion body; and a rear surface electrode having a second current-collecting electrode and a number N of line electrodes connected to the second current-collecting electrode. In the solar cell, the front surface electrode, the semiconductor substrate and the rear surface electrode are arranged in that order. The non-straight line electrodes of the front surface electrode and the line electrodes of the rear surface electrodes are disposed so as to face each other with the semiconductor substrate interposed between. Each of the non-straight line electrodes of the front surface electrode and a corresponding one of the line electrodes of the rear surface electrode are different in shape while having a portion where the electrodes intersect each other when viewed in a direction perpendicular to the front surface of the semiconductor substrate.

According to the first aspect of the invention, it is possible to alleviate the stresses on the front surface electrode and the rear surface electrode in substantially the same direction. As a result, the occurrence of cracks in the substrate can be prevented and the production yield can be improved.

In addition, the line electrodes of the front surface electrode have a non-straight shape. This shape allows a large tolerance for attachment accuracy in manufacturing when a conductive member is attached to the line electrodes for connecting adjacent solar cells with each other. Thus, the manufacturing costs can be reduced.

The line electrodes of the rear surface electrode may have a non-straight shape. When the line electrodes of the rear surface electrode have a non-straight shape, the tolerance for attachment accuracy in manufacturing can be made large.

Each of the first current-collecting electrode and the second current-collecting electrode may include a plurality of finger electrodes.

In a case where both of the first current-collecting electrode and the second current-collecting electrode include the plurality of finger electrodes, it is possible to reduce the amount of the electrode material, and to alleviate the stresses on the front surface side and the rear surface side in substantially the same direction. Accordingly, the occurrence of cracks in the substrate can be prevented and the production yield can be improved.

In addition, in the case where the first current-collecting electrode and the second current-collecting electrode include the plurality of finger electrodes, a transparent conductive film made of ITO or the like to improve the power collection may be interposed between the front surface electrode and the semiconductor substrate. In addition, a transparent conductive film made of ITO or the like to improve the power collection may be interposed between the rear surface electrode and the semiconductor substrate in this case.

Moreover, the front surface electrode and the rear surface electrode may be formed by curing or baking a conductive paste.

Line width Wb of each of the non-straight line electrodes of the front surface electrode and the non-straight line electrodes of the rear surface electrode is preferably between 50 μm to 200 μm, and more preferably, between 80 μm to 150 μm in view of reducing the amount of electrode material, and of preventing the occurrence of printing distortion when the front surface electrode and the rear surface electrode are formed by a screen-printing method.

It is preferable that line width Wb of each of the non-straight line electrodes of the front surface electrode and the non-straight line electrodes of the rear surface electrode be substantially the same as line width Wf of each of the finger electrodes. For example, Wf/Wb is preferably between 0.5 and 1, and more preferably, between 0.7 and 0.9.

Note that, line widths Wb of the non-straight line electrodes of the front surface electrode and the non-straight line electrodes of the rear surface electrode do not have to be the same.

In a case where only one of the first current-collecting electrode and the second current-collecting electrode includes finger electrodes, the aforementioned effects may be reduced, but the same results can be obtained. In this case, the one of the current-collecting electrodes including the plurality of finger electrodes is preferably positioned on the light receiving surface side. On the other side, for example, a current-collecting electrode made of a metal film may be formed substantially on the entire surface of the surface opposite to the light receiving surface of the semiconductor substrate forming the solar cell. In this case, a transparent conductive film such as ITO to improve the power collection may be interposed between the semiconductor substrate and the front surface electrode or the rear surface electrode on the light receiving surface side.

Although the effects are reduced, the same results can be obtained in the case of a configuration in which a first translucent current-collecting electrode formed of a thin metal film or the like and a second translucent current-collecting electrode formed of a thin metal film or the like are formed on substantially the entire surface regions on the first and second opposite surfaces of the semiconductor substrate forming the solar cell, respectively.

The line electrode of the front surface electrode and the line electrode of the rear surface electrode may have shapes symmetrical to each other.

In the case where the line electrode of the front surface electrode and the line electrode of the rear surface electrode have shapes symmetrical to each other, it is possible to further alleviate the addition of the stresses on the front surface electrode and the rear surface electrode in substantially the same direction, so that the occurrence of cracks in the substrate can be further prevented. Accordingly, the production yield can be improved.

In addition, the shape of the line electrodes of the front surface electrode and the shape of the line electrodes of the rear surface electrode are preferably in a reverse relationship when viewed in a direction perpendicular to the front surface.

Each of the line electrodes of the front surface electrode and the line electrodes of the rear surface electrode may have a thin line shape.

In this case, it is possible to further alleviate the addition of the stresses on the front surface electrode and the rear surface electrode in substantially the same direction. Accordingly, the occurrence of a crack in the substrate can be prevented, so that the production yield can be improved. In addition, the amount of electrode material can be reduced.

A second aspect of the invention provides a solar cell module including a plurality of solar cells according to the first aspect and a conductive connection member to electrically connect the plurality of solar cells with one another.

With the solar cell module according to the second aspect of the invention, the production yield can be improved.

A third aspect of the invention provides a solar cell system including the solar cell module according to the second aspect.

With the solar cell system according to the third aspect of the invention, the production yield can be improved.

### BRIEF DESCRIPTION OF THE DRAWINGS

FIG. 1 is a top view of a solar cell module according to a first embodiment of the invention.

FIG. 2 is a perspective view of the solar cell module.

FIG. 3 is a partial cross-sectional view taken along the line A-A′ of FIG. 1.

FIG. 4A is a top view of a solar cell of the solar cell module of FIG. 1. FIG. 4B is a bottom view of the solar cell.

FIG. 5A is a front side plan view of the solar cell for describing the connection between the solar cell in the solar cell module and conductive connection members. FIG. 5B is a partial schematic cross-sectional view taken along the line A-A′ of FIG. 5A.

FIG. 6A is a partial schematic cross-sectional view taken along the line B—B′ of FIG. 5A. FIG. 6B is a partial schematic cross-sectional view taken along the line C-C′ of FIG. 5A.

FIG. 7 is a top view of a solar cell in a solar cell module as a comparison example.

FIG. 8A is a top view of a solar cell of a solar cell module according to a second embodiment of the invention. FIG. 8B is a bottom view of the solar cell.

FIG. 9A is a top view of a solar cell of a solar cell module according to a third embodiment of the invention. FIG. 9B is a bottom view of the solar cell.

FIG. 10A is a top view of a solar cell of a solar cell module according to a fourth embodiment of the invention. FIG. 10B is a bottom view of the solar cell.

FIG. 11A is a top view of a solar cell of a solar cell module according to a fifth embodiment of the invention. FIG. 11B is a bottom view of the solar cell.

### DETAILED DESCRIPTION OF EMBODIMENTS

Embodiments of the invention are described with reference to the drawings. Note that, the same reference numerals are used to denote the same or equivalent portions in the drawings, and the description of the portions are not repeated in order to avoid redundant description.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

### First Embodiment

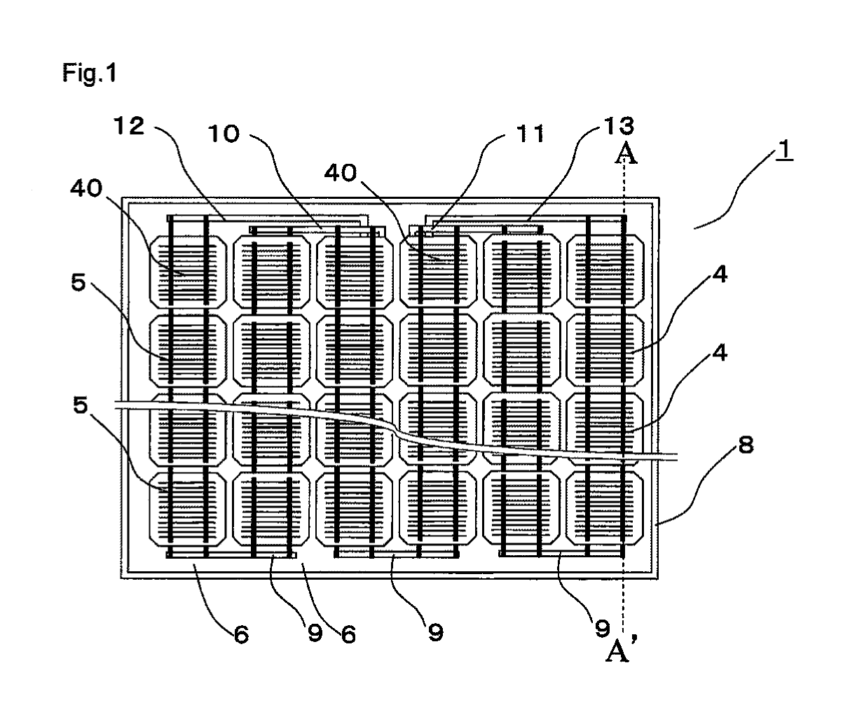

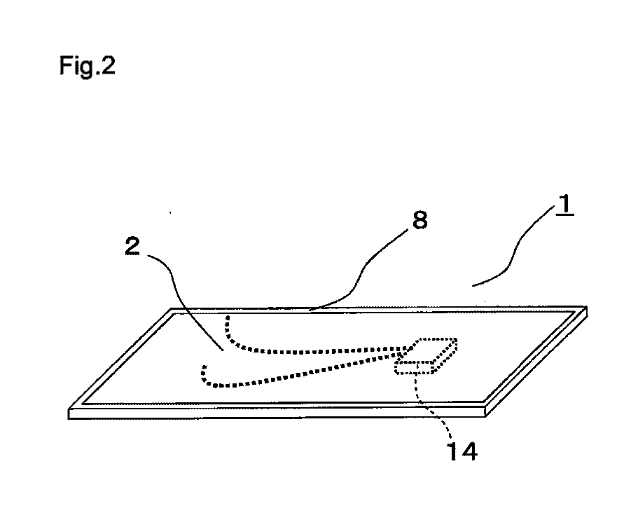

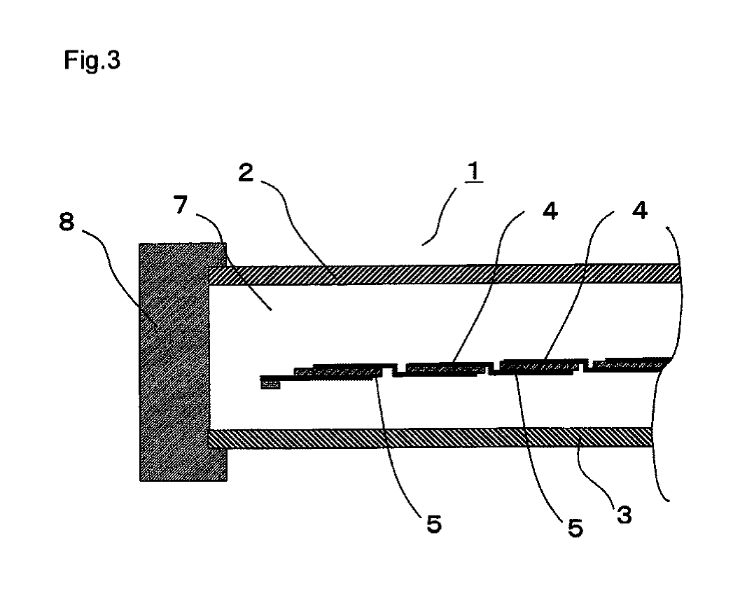

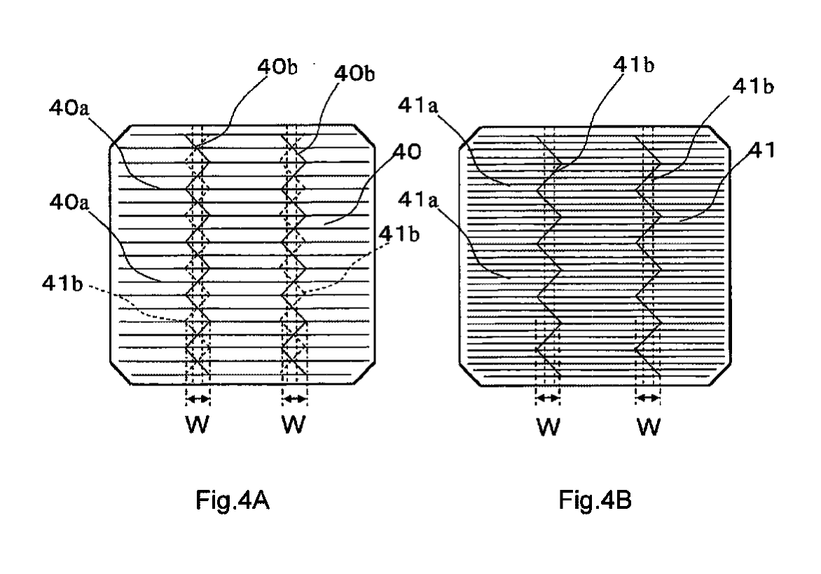

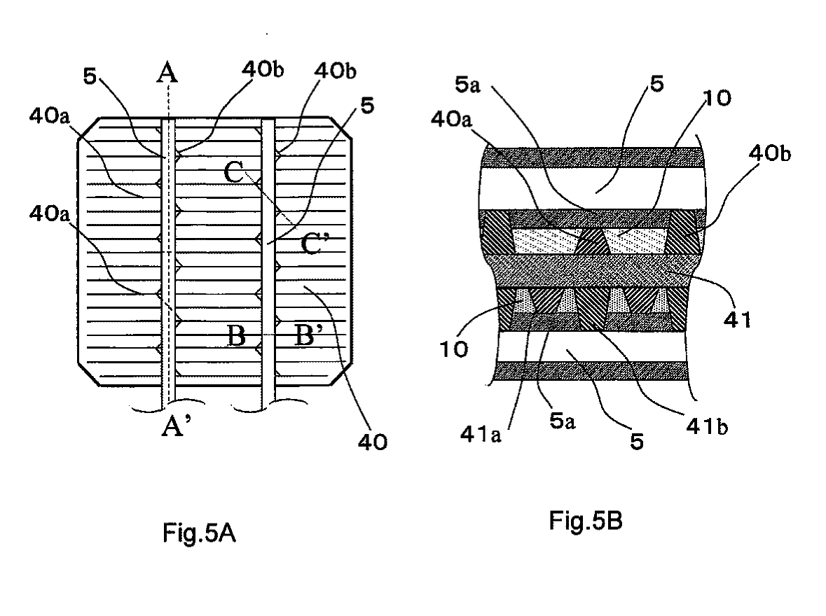

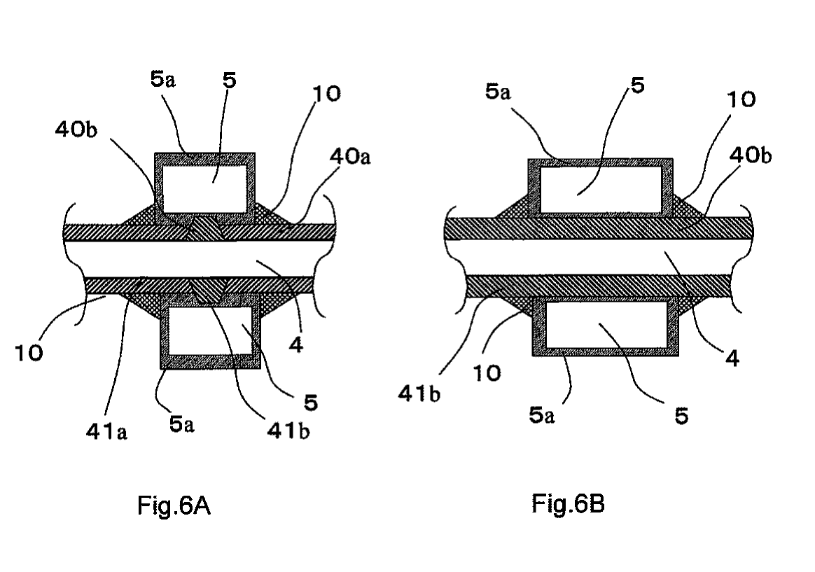

A solar cell module including a plurality of solar cells according to a first embodiment of the invention is described with reference to FIGS. 1 to 6B. FIG. 1 is a top view of the solar cell module according to the first embodiment of the invention. FIG. 2 is a perspective view of the solar cell module. FIG. 3 is a partial cross-sectional view taken along the line A-A′ of FIG. 1. FIG. 4A is a top view of the solar cell of the solar cell module of FIG. 1. FIG. 4B is a bottom view of the solar cell. FIG. 5A is a front side plan view provided for describing the connection between the solar cell and conductive connection members. FIG. 5B is a partial schematic cross-sectional view taken along the line A-A′ of FIG. 5A. FIG. 6A is a partial schematic cross-sectional view taken along the line B-B′ of FIG. 5A. FIG. 6B is a partial schematic cross-sectional view taken along the line C-C′ of FIG. 5A.

As shown in FIGS. 1 through 3, solar cell module 1 includes a rectangular plate-like structure and frame body 8 configured to support the outer peripheral edge of the structure. The structure includes: front cover 2; rear cover 3 disposed facing front cover 2 while being spaced from front cover 2; a plurality of solar cells 4 disposed between front cover 2 and rear cover 3 and arranged in a matrix on one planner surface; and filling member 4 used to fill the area between front cover 2 and rear cover 3, thus fixing the plurality of solar cells 4 to front cover 2 and rear cover 3.

Front cover 2 is a transparent member such as reinforced glass. Rear cover 3 is a weather-resistant member made of a resin film such as polyethylene terephthalate (PET). Solar cells 4 are electrically connected to each other by conductive connection members 5 serving as conductive members. Conductive connection members 5 are strip members each having a width of 1 to 2 mm and a thickness of 100 μm to 200 μm, and formed from copper foil or the like whose surface is coated with a lead-free solder layer (compliant layer) having a thickness of 20 μm to 40 μm. Frame body 8 is made of metal such as aluminum.

Solar cells 4 aligned linearly are connected in series by conductive connection members 5 and form one solar cell group 6. Solar cell groups 6 are arranged parallel with each other, and all solar cell groups 6 are electrically connected in series. Specifically, conductive connection members 5 at one ends (lower ends in FIG. 1) of predetermined adjacent solar cell groups 6 are solder-connected to each other by strip conductive connection member 9 made from flat plate copper wire or the like whose surface is coated with a lead-free solder layer having a width of 6 mm and a thickness of 300 μm. In addition, conductive connection members 5 at different ends (upper ends in FIG. 1) of different predetermined adjacent solar cell groups 6 are solder connected to each other by L-shaped conductive connection member 10 or 11 made from flat plate copper wire or the like whose surface is coated with a lead-free solder layer having a width of 3 mm and a thickness of 300 μm.

L-shaped conductive connection members (output extraction connection members) 12 and 13 are solder connected respectively to pairs of connection members 5 of solar cells 4 each positioned at the outermost edge of the electric power extraction side in a corresponding one of solar cell groups 6 positioned outermost. Each of L-shaped conductive connection members 12 and 13 is provided to extract electrical output from solar cell module 1 and is made of a solder-plated flat plate copper wire having a width of 6 mm and a thickness of 300 μm.

Note that, an insulating member (not shown) such as an insulating sheet made of polyethylene terephthalate (PET) or the like is interposed at each point where L-shaped connection members 10 and 11 described above intersect with L-shaped connection members 12 and 13 described above, respectively.

In addition, although not illustrated, a leading end portion of each of L-shaped connection members 10, 11, 12 and 13 described above is guided, via a slit provided at rear cover 3, to the inside of terminal box 14 provided at an upper center portion of solar cell module 1. In terminal box 14, bypass diodes (not shown) are provided to make connections between L-shaped connection members 12 and 10, between L-shaped connection members 10 and 11 and between L-shaped connection member 11 and 13, respectively.

Referring to FIGS. 4A through 6B, each of solar cells 4 has front surface electrode 40 including a plurality of narrow linear finger electrodes (current-collecting electrode) 40a disposed on the front surface thereof so as to cover substantially the entire front surface region, and two narrow-width saw-tooth like bus bar electrodes 40b connected to the plurality of narrow linear finger electrodes 40a. In addition, each of solar cells 4 has rear surface electrode 41 including a plurality of narrow linear finger electrodes (current-collecting electrode) 41a disposed on the rear surface thereof so as to cover substantially the entire rear surface region, and two narrow saw-tooth like bus bar electrodes 41b connected to the plurality of narrow-width linear finger electrodes 41a. Note that, each of two parallel linear strips indicated by dotted lines in FIGS. 4A and 4B indicates a portion where connection member 5 is disposed. In addition, saw-tooth dotted lines in FIG. 4A indicate the position of saw-tooth bus bar electrodes 41b of rear surface electrode 41 when viewed from the front surface side of solar cell 4 (direction perpendicular to the sheet surface of FIG. 4A).

Although not illustrated, each of solar cells 4 is a so-called HIT solar cell having a photoelectric conversion body in which an i-type amorphous silicon layer, one conductive type amorphous silicon layer of p-type or n-type and one transparent conductive film such as ITO are provided in the order named, substantially in the entire region on the front surface having the texture of an n-type single crystalline silicon substrate. In addition, in the photoelectric conversion body, an i-type amorphous silicon layer, an amorphous silicon layer of a conductive type opposite to the aforementioned conductive type and the other transparent conductive film such as ITO are provided in the order named, substantially in the entire region on the rear surface having the texture of the substrate, for example. Each of front surface electrode 40 and rear surface electrode 41 is fabricated by thermally curing a silver paste that is a thermosetting conductive paste including an epoxy resin as the binder and silver particles as the conductive base.

In addition, in adjacent solar cells 4, conductive connection member 5 is mechanically and electrically connected between bus bar electrodes 40b of front surface electrode 40 of one of adjacent solar cells 4 and bus bar electrodes 41b of rear surface electrode 41 of the other one of adjacent solar cells 4 by conductive adhesive agent 10 made of resin containing an epoxy resin and nickel particles serving as the conductive particles, for example.

The aforementioned adhesive agent may contain a conductive material such as conductive particles of solder, Ni, Ag or the like as described above. In addition, the adhesive agent may contain a non-conductive material such as non-conductive particles of silicon oxide or the like. The adhesive agent may contain both of the aforementioned conductive material and the non-conductive material, or may contain neither the conductive material nor the non-conductive material.

In front surface electrode 40, the average height of each bus bar electrode 40b is larger than the average height of each finger electrode 40a, and width W of each bus bar electrode 40b is larger than the width of each conductive connection member 5. Here, the average height refers to an average height along the center line positioned at the center of each line width of the bus bar electrode and the finger electrode in a range corresponding to conductive connection member 5 described above.

For example, each finger electrode 40a has a thickness (average height) selected from 30 μm to 80 μm and is a thin line having line width Wf selected from 50 μm to 120 μm. Moreover, finger electrodes 40a are arranged at a pitch of 2 mm. In addition, each bus bar electrode 40b has a thickness (average height) selected from 50 μm to 100 μm and is a thin line having line width Wb selected from 80 μm to 200 μm, for example.

Moreover, width W of each bus bar electrode 40b is greater than 1 mm but not greater than 2.5 mm.

In rear surface electrode 41, the average height of each bus bar electrode 41b is larger than the average height of each finger electrode 41a, and the line width of bus bar electrode 41b, which is width W, is larger than the width of each conductive connection member 5.

For example, each finger electrode 41a has a thickness (average height) selected from 20 μm to 60 μm and is a thin line having line width Wf selected from 50 μm to 150 μm. Moreover, finger electrodes 41a are arranged at a pitch of 1.2 mm. In addition, each bus bar electrode 41b has a thickness (average height) selected from 40 μm to 80 μm and is a thin line having line width Wb selected from 80 μm to 200 μm, for example. Moreover, width W of each bus bar electrode 41b is greater than 1 mm but not greater than 2.5 mm.

It is preferable that width Wb of each non-straight bus bar electrode 40b of front surface electrode 40 is substantially the same as width Wf of each finger electrode 40a or greater than width Wf of each finger electrode 40a. Likewise, it is preferable that width Wb of each non-straight bus bar electrode 41b of rear surface electrode 41 be substantially the same as width Wf of each finger electrode 41a or greater than width Wf of each finger electrode 41a. For example, it is preferable that Wf/Wb be equal to 0.5 to 1. More preferably, Wf/Wb is equal to 0.7 to 0.9.

In this embodiment, in front surface electrode 40, each bus bar electrode 40b is connected to compliant layer 5a of conductive connection member 5 while being buried deeply into compliant layer 5a in a large portion of the area. In addition, each finger electrode 40a is connected to compliant layer 5a of conductive connection member 5 while being buried shallowly into compliant layer 5a in a large portion of the area because the average height of finger electrode 40a is small as compared with bus bar electrode 40b. Here, finger electrodes 40a may be abutted on conductive connection member 5. Furthermore, finger electrodes 40a may not be buried into conductive connection member 5.

Likewise, in rear surface electrode 41, each narrow bus bar electrode 41b is connected to compliant layer 5a of conductive connection member 5 while being buried deeply into compliant layer 5a in a large portion of the area. In addition, each finger electrode 41a is connected to compliant layer 5a of conductive connection member 5 while being buried shallowly into compliant layer 5a in a large portion of the area because the average height of finger electrode 41a is small as compared with bus bar electrode 41b. Here, finger electrodes 41a may be abutted on conductive connection member 5. Furthermore, finger electrodes 41a may not be buried into conductive connection member 5.

As described above, connection members 5 are fixed to the front surfaces and rear surfaces of solar cells 4, bus bar electrodes 40b and 41b, and finger electrodes 40a and 41a by adhesive agent 10. In addition, bus bar electrodes 40b and 41b are buried into conduction members 5 in a good condition. With this configuration, connection members 5 are electrically and mechanically attached to solar cells 4 in a good state.

In this embodiment, each bus bar electrode 40b of front surface electrode 40 and a corresponding one of bus bar electrodes 41b of rear surface electrode 41 have shapes symmetrical to each other. In addition, each bus bar electrode 40b and a corresponding one of bus bar electrodes 41b are disposed facing each other while partially overlapping each other when viewed in a direction perpendicular to the front surface (direction perpendicular to the sheet surface of FIG. 4A) through the semiconductor substrate serving as the photoelectric conversion body. More specifically, bus bar electrodes 40b and 41b are disposed to have small overlapped portions at substantially even intervals in the longitudinal direction of connection members 5. In this embodiment, the overlapped portions are only positioned in the portions where connection members 5 are disposed (two stripes indicated by dotted lines in FIGS. 4A and 4B).

Accordingly, the addition of the stresses on the front surface side and the rear surface side in substantially the same direction is alleviated except for the overlapped portions, the stresses generated due to large differences between the thermal expansion coefficients of the aforementioned substrate and bus bar electrodes 40b of front surface electrode 40, and bus bar electrodes 41b of rear surface electrode 41. Thus, it is possible to suppress the occurrence of crack in the substrate.

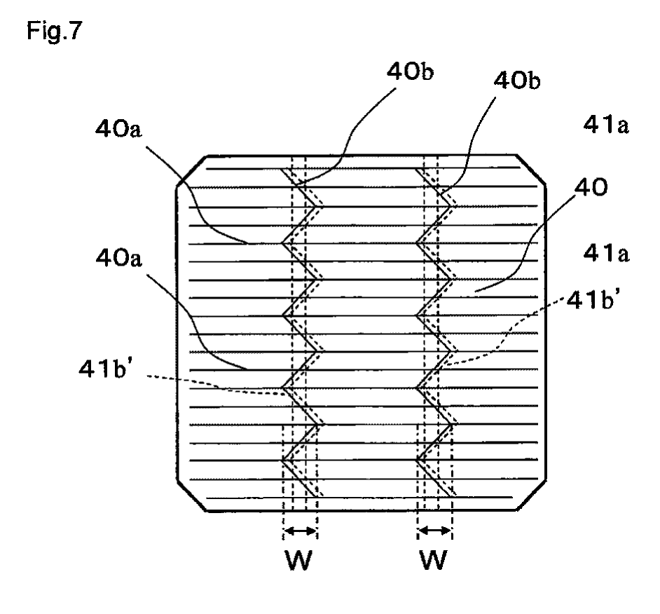

In contrast to this, in a case where bus bar electrodes 40b of front surface electrode 40 and bus bar electrodes 41b of rear surface electrode 41 are disposed while being in matched alignment with each other when viewed in the direction perpendicular to the front surface, the stresses on the front surface side and the rear surface side are added in substantially the same direction, so that there arises a concern that crack in the cell may occur. Moreover, in a case where bus bar electrodes 40b of front surface electrode 40 and bus bar electrodes 41b′ of rear surface electrode 41 are disposed while being slightly shifted from each other as shown in FIG. 7 because of the relationship with the accuracy at the time of manufacturing, the possibility of the occurrence of a crack in the cell increases due to a shear stress because bus bar electrodes 40b and bus bar electrodes 41b″ of rear surface electrode 41 are narrow-width shaped.

In addition, as to the connection between connection members 5 and solar cells 4, as compared with connection strength A between solar cells 4 and the aforementioned transparent conductive layers of solar cells 4, connection strength B with bus bar electrodes 40b of front surface electrode 40 and bus bar electrodes 41b of rear surface electrode 41 is high. Thus, the effect of suppressing the occurrence of a crack in the substrate, which is brought about by reducing the overlapped portions of bus bar electrodes 40b of front surface electrode 40 and bus bar electrodes 41b of rear surface electrode 41, increases as compared with a case where connection strength A is higher than connection strength B.

In this embodiment, since width W of each of bus bar electrodes 40b and bus bar electrodes 41b is larger than the line width of the conductive connection member, the accuracy required in the arrangement of conductive connection members 5 with bus bar electrodes 40b and 41b may be low, so that the manufacturing time can be reduced, and thus the manufacturing costs can be also reduced.

In this embodiment, front surface electrode 40 includes thin line shaped finger electrodes 40a and thin line shaped bus bar electrodes 40b, and rear surface electrode 41 includes thin line shaped finger electrodes 41a and thin line shaped bus bar electrodes 41b, so that the amount of the material of the electrodes can be reduced.

In this embodiment, in addition to finger electrodes 40a and 41a, bus bar electrodes 40b and 41b are thin line shaped, so that bus bar electrodes 40b and 41b can be inserted into conductive connection members 5 with a good condition without increasing the pressing force of the conductive connection members to the bus bar electrodes as compared with conventional wide bus bar electrodes. Thus, good electrical connections between connection member 5 and surface electrode 40, and rear surface electrode 41 can be achieved.

In addition, each of bus bar electrodes 40b and 41b has a saw-tooth shape, i.e., not a linear shape (non-straight shape), so that the portions where connection members 5 and bus bar electrodes 40b and 41b are in contact with each other increase as compared with a case where each of the bus bar electrodes is a thin linear line. Accordingly, good electrical connections between connection members 5 and front surface electrode 40, and rear surface electrode 41 can be obtained. Moreover, in addition to the increase of the contact portions, the external force is dispersed, so that the reliability of the mechanical connection is high.

In addition, in this embodiment, the average height of each of bus bar electrodes 40b and 41b is larger than the average height of a corresponding one of finger electrodes 40a and 41a. Accordingly, in the mechanical connections of front surface electrode 40 and rear surface electrode 41 to the conductive connection members, bus bar electrodes 40b and 41b become more dominant than finger electrodes 40a and 41a.

As a result, bus bar electrodes 40b and 41b can be inserted into the conductive connection members without increasing the pressing force of conductive connection members 5 to bus bar electrodes 40b and 41b as compared with the conventional wide bus bar electrodes. Thus, good electrical connections between connection members 5 and front surface electrode 40, and rear surface electrode 41 can be obtained. In addition, in the case where the number of finger electrodes 40a of front surface electrode 40 and the number of finger electrodes 41a of rear surface electrode 41 are different as in the case of the embodiment, the difference between the stresses on the rear surface side and the front surface side can be small, and the occurrence of cracks in the cell can be further prevented, thus, making it possible to achieve a good production yield.

Moreover, since the average height of each of finger electrodes 40a and 41a is smaller than the average height of a corresponding one of bus bar electrodes 40b and 41b, it is possible to suppress adhesive agent 10 from spreading along the finger electrode as compared with a case where the average height of the finger electrode is large.

Moreover, in this embodiment, width W of each bus bar electrode 40b and width W of each bus bar electrode 41b are larger than the line width of the conductive connection member, so that even if adhesive agent 10 spreads, the spreading of adhesive agent 10 can be suppressed in the portions where bus bar electrodes 40b protrude. Thus, the amount of spreading of adhesive agent 10 can be suppressed to be within the portions.

### (Manufacturing Method of the Solar Cell Module)

Hereinafter, a manufacturing method of the solar cell module according to the first embodiment is described.

First, an epoxy-base thermosetting silver paste is printed on the transparent electrode film layer on the front surface side of solar cell 4 by a screen-printing method. Then, the silver paste is completely cured by a heating process for one hour at a temperature of 200° C. to form front surface electrode 40. Thereafter, an epoxy-base thermosetting silver paste is printed on the transparent electrode film layer on the rear surface side of solar cell 4 by a screen-printing method in the same manner. Then, the silver paste is completely cured by a heating process for one hour at a temperature of 200° C. to form rear surface electrode 41.

Here, in this embodiment, in order that the average height of each of bus bar electrodes 40b and 41b is higher than the average height of a corresponding one of finger electrodes 40a and 41a, the width of each of bus bar electrodes 40b and 41b is set larger than the width of a corresponding one of finger electrodes 40a and 41a, and the printing speed of the aforementioned screen-printing is also controlled. Note that, alternatively, it is also possible to perform the screen-printing twice by using different printing plates so that the average height of each of bus bar electrodes 40b and 41b becomes larger than the average height of a corresponding one of finger electrodes 40a and 41a.

Next, plural connection members 5 are prepared, and adhesive agent 10 is applied by use of a dispenser onto a portion on one of the surfaces of each connection member 5, which faces solar cell 4, and a portion on the other one of the surfaces of connection member 5, which faces solar cell 4 adjacent to solar cell 4 mentioned above, to have a thickness of approximately 30 μm.

Next, plural connection members 5 are arranged so that the surfaces of each connection member 5 onto which adhesive agent 10 described above is applied face bus bar electrode 40b of front surface electrode 40 of one of adjacent solar cells 4, and bus bar electrode 41b of rear surface electrode 41 of the other one of adjacent solar cells 4, respectively. The adhesive agent is then cured in this state by a heating process for one hour at a temperature of 200° C. while a pressure of approximately 2 MPa is applied, thereby making solar cell group 6. Here, the pressure is applied during the heating process, so that bus bar electrodes 40h and 41b are inserted into compliant layers 5a of connection members 5. Here, connection members 5 on which adhesive agent 10 is formed are prepared in order to bond solar cells 4 to connection members 5. However, the adhesive material may be prepared by applying adhesive agent 10 on solar cells 4. Moreover, a film like adhesive material may be prepared as adhesive agent 10, and may be disposed on bus bar electrodes 40b and 41b. Then, the heating process may be performed while the pressure is applied in a state where connection members 5 are disposed on the adhesive material.

Next, plural solar cell groups 6 are prepared. Then, an assembly is fabricated in which connection members 9 and connection members 10, 11, 12 and 13 are attached to plural solar cell groups 6. Front cover 2, a sealing sheet serving as a sealing member, the structure, a sealing sheet serving as a sealing member, and rear cover 3 are stacked in that order. Then, the stacked members are pressure bonded to one another in vacuum by a heating process for 10 minutes at a temperature of 150° C. Thereafter, the stacked members are completely cured by a heating process for one hour at a temperature of 150° C.

Last, terminal box 14 and metal frame 8 are attached to the aforementioned cured members, and solar cell module 1 is thus completed.

### Second Embodiment

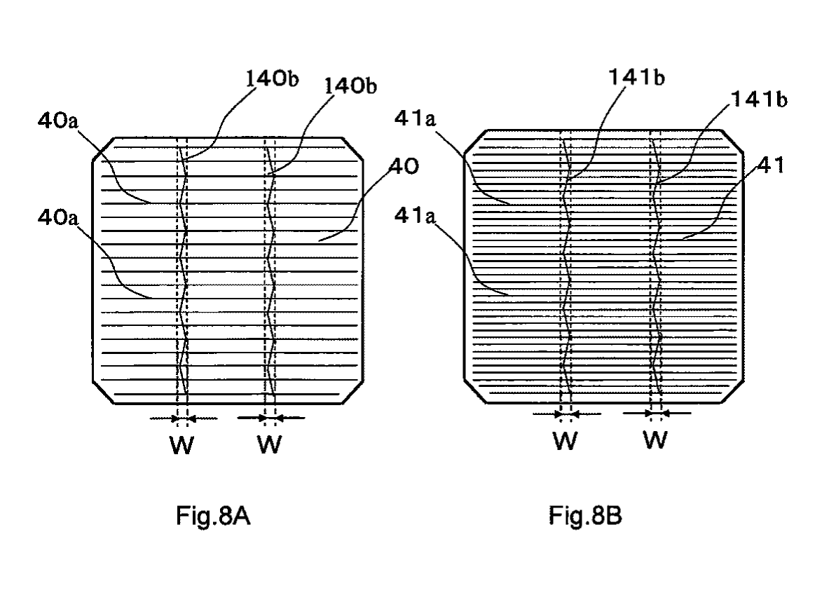

A solar cell module according to a second embodiment of the invention is described with reference to FIGS. 8A and 8B. FIG. 8A is a top view of a solar cell in the solar cell module according to this embodiment. FIG. 8B is a bottom view of the solar cell. Here, differences from the first embodiment are mainly described.

Referring to FIGS. 8A and 8B, each of solar cells 4 has front surface electrode 40 including a plurality of narrow linear finger electrodes 40a disposed on the front surface thereof so as to cover substantially the entire front surface region, and two narrow saw-tooth like bus bar electrodes 140b connected to the plurality of narrow finger electrodes 40a. In addition, each of solar cells 4 has rear surface electrode 41 including a plurality of narrow linear finger electrodes 41a disposed on the rear surface thereof so as to cover substantially the entire rear surface region, and two narrow saw-tooth like bus bar electrodes 141b connected to the plurality of narrow linear finger electrodes 41a.

The second embodiment is different from the first embodiment in that width W of each bus bar electrode 140b of front surface electrode 40 is configured to be the same as or smaller than the width of each conductive connection member 5, and that width W of each bus bar electrode 141b of rear surface electrode 41 is configured to be the same as or smaller than the width of each conductive connection member 5.

For example, each finger electrode 40a has a thickness (average height) selected from 30 μm to 80 μm and line width Wf selected from 50 μm to 120 μm. Moreover, finger electrodes 40a are arranged at a pitch of 2 mm. In addition, each bus bar electrode 140b has a thickness (average height) selected from 50 μm to 100 μm and line width Wb selected from 80 μm to 200 μm, for example. Moreover, width W of each bus bar electrode 140b is between 0.5 to 1 mm.

In rear surface electrode 41, the average height of each bus bar electrode 141b is larger than that of each finger electrode 41a, and the line width of each bus bar electrode 141b, which is width W of each bus bar electrode 141b, is equal to or smaller than the width of each conductive connection member 5.

For example, each finger electrode 41a has a thickness (average height) selected from 20 μm to 60 μm and line width Wf selected from 50 μm to 150 μm. Moreover, finger electrodes 41a are arranged at a pitch of 1.2 mm. In addition, each bus bar electrode 141b has a thickness (average height) selected from 40 μm to 80 μm and line width Wb selected from 80 μm to 200 μm, for example. Moreover, width W of each bus bar electrode 141b is between 0.5 to 1 mm.

It is preferable that width Wb of each non-straight bus bar electrode 140b of front surface electrode 40 be substantially the same as width Wf of each finger electrode 40a or greater than width Wf of each finger electrode 40a. Likewise, it is preferable that width Wb of each non-straight bus bar electrode 141b of rear surface electrode 41 be substantially the same as width Wf of each finger electrode 41a or greater than width Wf of each finger electrode 41a. For example, it is preferable that Wf/Wb be equal to 0.5 to 1. More preferably, Wf/Wb is equal to 0.7 to 0.9.

In this embodiment as well, bus bar electrodes 40b of front surface electrode 40 and bus bar electrodes 141b of rear surface electrode 41 are disposed facing each other so that portions where bus bar electrodes 40b and bus bar electrodes 141b overlap with each other is small when viewed from the front surface side through the photoelectric conversion body (direction perpendicular to the sheet surface of FIG. 7). In this embodiment, the overlapped portions are only where connection members 5 are arranged.

Accordingly, addition of the stresses on the front surface and the rear surface in substantially the same direction is alleviated except for the overlapped portions, as well as the stresses generated due to large differences between the thermal expansion coefficients of the aforementioned substrate and bus bar electrodes 140b of front surface electrode 40, and bus bar electrodes 141b of rear surface electrode 41. Thus, it is possible to suppress the occurrence of cracks in the substrate.

In addition, as to the connection between connection members 5 and solar cell 4, compared with the connection strength of the aforementioned transparent conductive film layers of solar cell 4, the connection strength of bus bar electrodes 140b of front surface electrode 40, and bus bar electrodes 141b of rear surface electrode 41 is high. Accordingly, reduction of the overlapped portions of bus bar electrodes 140b of front surface electrode 40 and bus bar electrode 141b of rear surface electrode 41, which are disposed facing each other when viewed from the front surface (direction perpendicular to the sheet surface in FIG. 7) further suppresses the occurrence of cracks in the substrate.

In this embodiment, the production yield is improved compared with the prior art as in the case of the first embodiment. Further, in this embodiment, the amount of electrode material is further reduced compared with the first embodiment. The portions where connection members 5 and bus bar electrodes 140b and 141b face each other are increased, and bus bar electrodes 140b and 141b can be thus pressed into the conduction connection members in good condition. Thus, good electrical connection between connection members 5 and front surface electrode 40, and rear surface electrode 41 is obtained.

### Third Embodiment

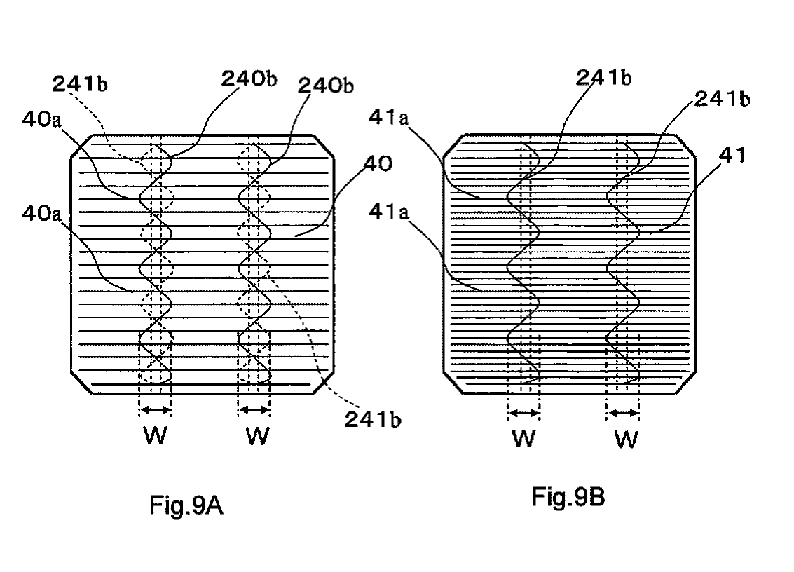

A solar cell module according to a third embodiment of the invention is described with reference to FIGS. 9A and 9B. FIG. 9A is a top view of a solar cell in the solar cell module according to this embodiment. FIG. 9B is a bottom view of the solar cell. Here, differences from the first embodiment are mainly described.

Referring to FIGS. 9A and 9B, each of solar cells 4 has front surface electrode 40 including a plurality of narrow linear finger electrodes 40a disposed on the front surface thereof so as to cover substantially the entire front surface region, and two narrow wave like bus bar electrodes 240b connected to the plurality of narrow linear finger electrodes 40a. Each narrow linear finger electrode 40a has width Wf equal to 60 μm, and each narrow wave like bus bar electrode 240b has width W equal to 1.5 mm, for example. In addition, each of solar cells 4 has rear surface electrode 41 including a plurality of narrow linear finger electrodes 41a disposed on the rear surface thereof so as to cover substantially the entire rear surface region, and two narrow wave-like bus bar electrodes 241b connected to the plurality of narrow linear finger electrodes 41a. Each narrow linear finger electrode 41a has width Wf equal to 80 μm, and each narrow wave like bus bar electrode 241b has width W equal to 1.5 mm, for example.

Although the amount of electrode material used for front surface electrode 40 and rear surface electrode 41 increases a little in the third embodiment as compared with the first embodiment, in addition to the effect obtained in the first embodiment, other effects are obtained.

### Fourth Embodiment

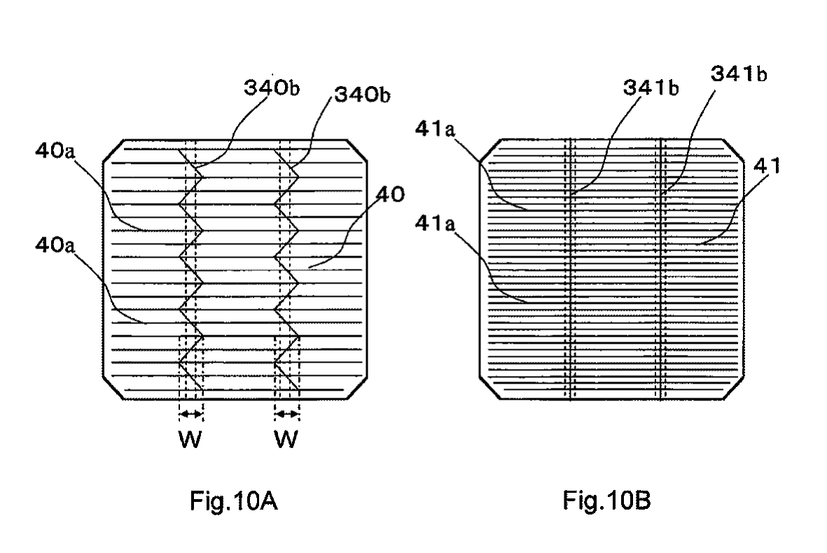

A solar cell module according to a fourth embodiment of the invention is described with reference to FIGS. 10A and 10B.

FIG. 10A is a top view of a solar cell in the solar cell module according to this embodiment. FIG. 10B is a bottom view of the solar cell. Here, differences from the first embodiment are mainly described.

Referring to FIGS. 10A and 10B, each of solar cells 4 has front surface electrode 40 including a plurality of narrow linear finger electrodes 40a disposed on the front surface thereof so as to cover substantially the entire front surface region, and two narrow saw-tooth like bus bar electrodes 340b connected to the plurality of narrow linear finger electrodes 40a. Each narrow linear finger electrode 40a has width Wf equal to 60 μm, and each narrow saw-tooth like bus bar electrode 340b has width W equal to 1 mm, for example. In addition, each of solar cells 4 has rear surface electrode 41 including a plurality of narrow linear finger electrodes 41a disposed on the rear surface thereof so as to cover substantially the entire rear surface region, and two narrow linear bus bar electrodes 341b connected to the plurality of narrow linear finger electrodes 41a. Each narrow linear finger electrode 41a has width Wf equal to 80 μm, and each narrow linear bus bar electrode 341b has width Wb equal to 0.3 mm, for example.

In this embodiment, the production yield is improved compared with the prior art as in the case of the first embodiment.

Moreover, in this embodiment, the amount of electrode material for the rear surface electrode is further reduced compared with the first embodiment.

### Fifth Embodiment

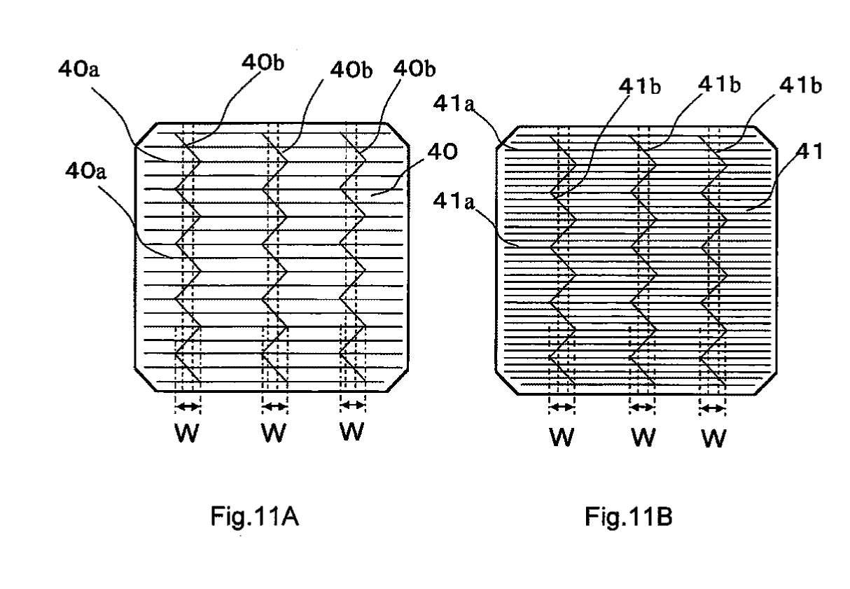

A solar cell module according to a fifth embodiment of the invention is described with reference to FIGS. 11A and 11B. FIG. 11A is a top view of a solar cell in the solar cell module according to this embodiment. FIG. 11B is a bottom view of the solar cell. Here, differences from the first embodiment are mainly described.

The fifth embodiment is different from the first embodiment in that front surface electrode 40 has three bus bar electrodes 40b and rear surface electrode 41 has three bus bar electrodes 41b.

In this embodiment, the production yield is improved compared with the prior art as in the case of the first embodiment. Further, since each of the front surface electrode and the rear surface electrode has three bus bar electrodes, the power collection efficiency increases.

### Sixth Embodiment

Next, a solar cell system according to a sixth embodiment of the invention is described.

The solar cell system according to this embodiment is a solar cell system comprised of a plurality of solar cell modules 1 of one of the first to fifth embodiments and installed on the roof of a residential house in a direction from the under side (eave side) to the over side (ridge side) in a superposed manner (in a step-like shape). Each of solar cell modules 1 is attached to the surface of the roof with fixing screws, and adjacent solar cell modules 1 are engaged with each other. The solar cell system also has a controller for the solar cell modules.

Although the aforementioned solar cell system is used for a residential house, for example, the invention is not limited to this, and the installation method of the solar cell modules can be changed as appropriate.

Although the solar cells in each of the aforementioned embodiments are described using so called HIT solar cells, various solar cells such as single crystalline solar cells or polycrystalline solar cells can be appropriately used. In addition, the invention can be applied to a single-sided solar cell, in addition to a bifacial solar cell.

The aforementioned polycrystalline solar cell or single crystalline solar cell may be a solar cell configured in the following manner. For example, an n+ layer is formed in a predetermined depth from a surface of a P-type polycrystalline or P-type single crystalline silicon substrate to form a pn junction, and then, a p+ layer is formed in a predetermined depth from the rear surface of the substrate. Then, front surface electrode 40 is formed on the n+ layer, and rear surface electrode 41 is formed on the p+ layer, for example.

In addition, in a case where both of the bus bar electrodes of the front surface electrode and the bus bar electrodes of the rear surface electrode are non-straight line electrodes, widths W of the bus bar electrodes may be the same or different.

Moreover, in each of the embodiments, a resin adhesive agent is used to connect connection members 5 with the front surface electrode and the rear surface electrode, but solder may be used for the connection. In addition, it is possible to employ a configuration in which both of a resin adhesive agent and solder are used for the connection.

Furthermore, in each of the embodiments, both of the front surface electrode and the rear surface electrode include finger electrodes and bus bar electrodes. However, the invention can be applied to a configuration in which the front surface electrode includes finger electrodes and bus bar electrodes, and the rear surface electrode includes electrodes of a different structure, e.g., a structure in which the entire surface of the electrode is covered with a metal film.

Moreover, connection members 5 may be provided with asperities on the surface thereof.

Furthermore, the number of bus bar electrodes of each of the front surface electrode and the rear surface electrode is two or three in each of the embodiments. The number of bus bar electrodes can be appropriately changed, however.

What is claimed is:

1. A solar cell comprising:
a front surface electrode having a first current-collecting electrode and a number N of non-straight line electrodes connected to the first current-collecting electrode;
a semiconductor substrate serving as a photoelectric conversion body; and
a rear surface electrode having a second current-collecting electrode and the number N of line electrodes connected to the second current-collecting electrode, the front surface electrode, the semiconductor substrate and the rear surface electrode being arranged in that order, wherein
the non-straight line electrodes of the front surface electrode and the line electrodes of the rear surface electrode are opposed to each other with the semiconductor substrate interposed there-between, and
each of the non-straight line electrodes of the front surface electrode and a corresponding one of the line electrodes of the rear surface electrode are different in shape while having a portion where the electrodes intersect each other as viewed in a direction perpendicular to the front surface of the semiconductor substrate.

2. The solar cell according to claim 1, wherein each of the first current-collecting electrode and the second current-collecting electrode includes a plurality of finger electrodes.

3. The solar cell according to claim 1, wherein the line electrode of the front surface electrode and the line electrode of the rear surface electrode have shapes symmetrical to each other.

4. The solar cell according to claim 1, wherein each of the line electrode of the front surface electrode and the line electrode of the rear surface electrode has a thin line shape.

5. The solar cell according to claim 4, wherein a transparent conductive film is interposed between the front surface electrode and the semiconductor substrate.

6. The solar cell according to claim 4, wherein a transparent conductive film is interposed between the rear surface electrode and the semiconductor substrate.

7. The solar cell according to claim 1, wherein each of the front surface electrode and the rear surface electrode is formed from a conductive paste.

8. The solar cell according to claim 1, wherein line width. Wb of the non-straight line electrode of the front surface electrode is between 50 μm to 200 μm.

9. The solar cell according to claim 8, wherein line width Wb of the non-straight line electrode of the front surface electrode is between 80 μm to 150 μm.

10. The solar cell according to claim 1, wherein the line electrode of the rear surface electrode has a non-straight line shape.

11. The solar cell according to claim 10, wherein line width Wb of the non-straight line electrode of the rear surface electrode is between 50 μm to 200 μm.

12. The solar cell according to claim 11, wherein line width Wb of the non-straight line electrode of the rear surface electrode is between 80 μm to 150 μm.

13. The solar cell according to claim 10, wherein a ratio of line width Wb of each of the non-straight line electrodes of the front surface electrode and the non-straight line electrodes of the rear surface electrode with respect to line width Wf of each of the finger electrodes, which is Wf/Wb, is between 0.5 and 1.

14. The solar cell according to claim 13, wherein the ratio of line width Wb of each of the non-straight line electrodes of the front surface electrode and the non-straight line electrodes of the rear surface electrode with respect to line width Wf of each of the finger electrodes, which is Wf/Wb, is between 0.7 and 0.9.

15. A solar cell module comprising:
a plurality of solar cells according to claim 1; and
a conductive connection member configured to electrically connect the plurality of solar cells with one another.

16. A solar cell system comprising the solar cell module according to claim 15.
